(19) United States
(12) Patent Application Publication
(10) Pub. No.: US 2026/0265459 A1
(43) Pub. Date: Sep. 10, 2026

(54) POLYIMIDE PRECURSOR COMPOSITION, POLYIMIDE FILM, LAMINATE, ELECTRONIC DEVICE, METHOD OF PRODUCING LAMINATE, METHOD OF PRODUCING POLYIMIDE FILM, AND METHOD OF PRODUCING ELECTRONIC DEVICE

(71) Applicant: KANEKA CORPORATION, Osaka (JP)

(72) Inventors: Hirofumi Nakayama, Otsu-shi (JP); Masayoshi Kido, Otsu-shi (JP); Nobuaki Tanaka, Otsu-shi (JP)

(73) Assignee: KANEKA CORPORATION, Osaka (JP)

(21) Appl. No.: 19/299,729

(22) Filed: Aug. 14, 2025

Related U.S. Application Data
(63) Continuation of application No. PCT/JP2024/005276, filed on Feb. 15, 2024.

(30) Foreign Application Priority Data
Feb. 15, 2023 (JP) 2023-021987

(51) Int. Cl. C08G 73/10; C08J 5/18

(52) U.S. Cl. CPC C08G 73/1085; C08J 5/18; C08J 2379/08

(57) ABSTRACT

A polyimide precursor composition containing a polyimide precursor and an organic solvent is provided. The polyimide precursor has a structural unit into which a specific xanthene structure has been introduced. The imidization ratio of the polyimide precursor is 10 mol % or more and less than 80 mol %. A method of producing a laminate including a support and a polyimide film is also provided. The method includes applying the polyimide precursor onto a support to form a coating film and heating the coating film, thereby imidizing the polyimide precursor to form a polyimide film on the support.

### TECHNICAL FIELD

One or more embodiments of the present invention relate to a polyimide precursor composition, a polyimide film, a laminate, an electronic device, a method of producing a laminate, a method of producing a polyimide film, and a method of producing an electronic device.

### BACKGROUND

With rapid progress of displays such as liquid crystal displays, organic electro-luminescence (organic ELs), and electronic papers and electronic devices such as solar cells and touch panels, devices have been progressively made thinner, lighter, and more flexible. In these devices, a polyimide is used as a substrate material instead of a glass substrate.

In these devices, various electronic elements such as a thin film transistor and a transparent electrode are formed on a substrate, and formation of these electronic elements needs a high-temperature process. A polyimide has heat resistance sufficient to be adaptable to a high-temperature process, and has a linear thermal expansion coefficient (CTE) close to that of a glass substrate or an electronic element, so that internal stress is less likely to occur. Thus, a polyimide is suitable for a substrate material for a flexible display and the like.

An aromatic polyimide is generally yellowish-brown color due to intramolecular conjugation or formation of a charge transfer (CT) complex. In top-emission type organic ELs and the like, light is extracted from the opposite side of a substrate, and therefore the substrate is not required to have transparency and has used a conventional aromatic polyimide. However, in a case where light emitted from a display element is emitted through a substrate as in a transparent display, a bottom emission type organic EL, or a liquid crystal display, or in a case where a sensor or a camera module is disposed on the back surface of a substrate in order to make a smartphone or the like a full-surface display (notchless), the substrate is also required to have high optical properties (more specifically, transparency and the like).

From such a background, there is a demand for a material that has heat resistance equivalent to that of an existing aromatic polyimide and is less colored and excellent in transparency.

Techniques of suppressing formation of a CT complex using an aliphatic monomer (Patent Documents 1 and 2), a technique of enhancing transparency by using a monomer having a fluorine atom (Patent Document 3), and a technique of enhancing transparency by introducing a xanthene structure (Patent Document 4) are known as techniques for thinning of the color of a polyimide.

The polyimides described in Patent Documents 1 and 2 have high transparency and a low CTE, but have a low thermal decomposition temperature because an aliphatic structure is included, and therefore these polyimides are difficult to apply to a high-temperature process at the time of forming an electronic element. The polyimide described in Patent Document 3 has high transparency because a fluorine atom is included, but has room for improvement in heat resistance.

### PATENT DOCUMENTS

Patent Document 1: JP 2016-29177 A
Patent Document 2: JP 2012-41530 A
Patent Document 3: JP 2014-70139 A
Patent Document 4: JP 2021-521284 A

According to the technique described in Patent Document 4, a polyimide having excellent transparency is obtained. However, the polyimide obtained with the method described in Patent Document 4 tends to have a relatively large CTE. Therefore, it is difficult to obtain a polyimide capable of reducing the CTE while enhancing the transparency only with the technique described in Patent Document 4.

### SUMMARY

In view of the above, and a polyimide capable of reducing the CTE while enhancing the transparency, and a polyimide precursor composition as a precursor of the polyimide are provided. Furthermore, a product or a member that is produced using the polyimide and the polyimide precursor composition and that is required to have heat resistance and transparency is also provided. In particular, a product or a member in which the polyimide film of one or more embodiments of the present invention is formed on a surface of an inorganic substance such as glass, a metal, a metal oxide, or single crystal silicon is provided.

An aspect of one or more embodiments of the present invention is as follows.
[1] A polyimide precursor composition including a polyimide precursor and an organic solvent,
   the polyimide precursor having a structural unit represented by General Formula (1) described below and a structural unit represented by General Formula (2) described below,

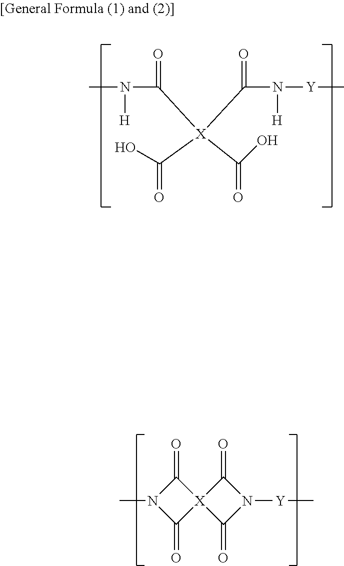

in which X includes one or more selected from the group consisting of a tetravalent organic group represented by Chemical Formula (3) described below and a tetravalent organic group represented by Chemical Formula (4) described below, and Y includes one or more selected from the group consisting of a divalent organic group represented by Chemical Formula (5) described below, a divalent organic group represented by Chemical Formula (6) described below, divalent organic groups represented by General Formula (7) described below, and divalent organic groups represented by General Formula (8) described below,

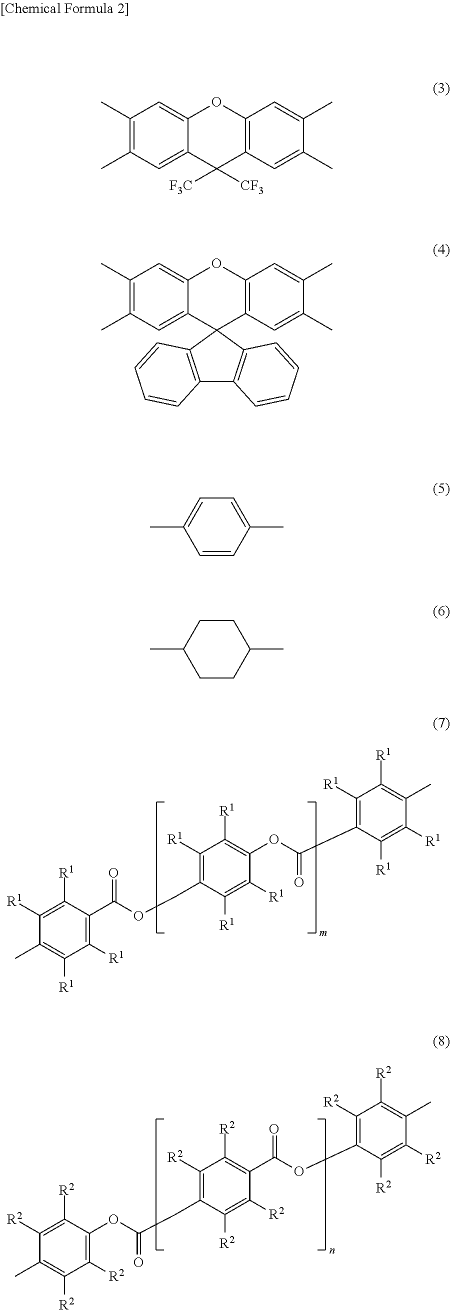

in which R¹ and R² each independently represent a monovalent organic group having 1 or more and 12 or less carbon atoms or represent a hydrogen atom, a plurality of R¹s are optionally equal to or different from each other, a plurality of R²s are optionally equal to or different from each other, and m and n each independently represent an integer of 0 or more and 3 or less,
   the polyimide precursor composition having a content of the structural unit represented by General Formula (2) of 10 mol % or more and less than 80 mol % with respect to a total amount of structural units in the polyimide precursor.
[2] The polyimide precursor composition according to [1], having a content of one or more residues of 50 mol % or more and 100 mol % or less with respect to a total amount of diamine residues in the polyimide precursor, the one or more residues selected from the group consisting of the divalent organic group represented by Chemical Formula (5), the divalent organic group represented by Chemical Formula (6), the divalent organic groups represented by General Formula (7), and the divalent organic groups represented by General Formula (8).
[3] The polyimide precursor composition according to [1] or [2], in which in General Formulas (1) and (2), X further includes one or more selected from the group consisting of a tetravalent organic group represented by Chemical Formula (9) described below, a tetravalent organic group represented by Chemical Formula (10) described below, a tetravalent organic group represented by Chemical Formula (11) described below, a tetravalent organic group represented by Chemical Formula (12) described below, and a tetravalent organic group represented by Chemical Formula (13) described below.

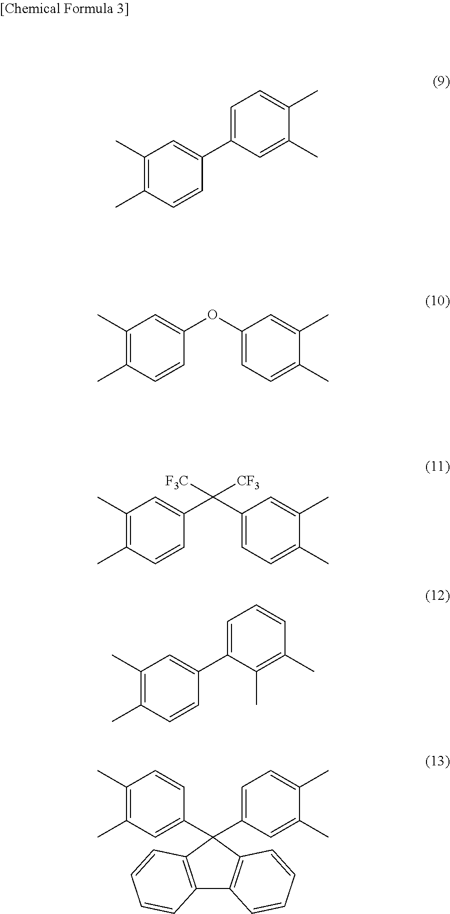

[4] The polyimide precursor composition according to [3], having a content of one or more residues of 5 mol % or more and 95 mol % or less with respect to a total amount of tetracarboxylic dianhydride residues in the polyimide precursor, the one or more residues selected from the group consisting of the tetravalent organic group represented by Chemical Formula (9), the tetravalent organic group represented by Chemical Formula (10), the tetravalent organic group represented by Chemical Formula (11), the tetravalent organic group represented by Chemical Formula (12), and the tetravalent organic group represented by Chemical Formula (13).
[5] The polyimide precursor composition according to any one of [1] to [4], in which the organic solvent is one or more selected from the group consisting of N-methyl-2-pyrrolidone, 1-butyl-2-pyrrolidone, 3-methoxy-N,N-dimethylpropanamide, 3-butoxy-N,N-dimethylpropanamide, N,N-dimethylpropionamide, N,N-diethylformamide, and 1,3-dimethyl-2-imidazolidinone.
[6] A polyimide film including a polyimide having a structural unit represented by General Formula (2) described below;

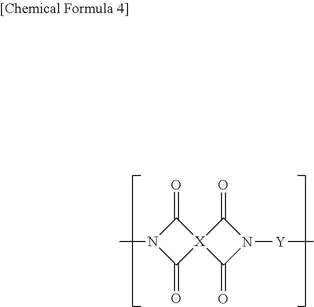

in which X includes one or more selected from the group consisting of a tetravalent organic group represented by Chemical Formula (3) described below and a tetravalent organic group represented by Chemical Formula (4) described below, and Y includes one or more selected from the group consisting of a divalent organic group represented by Chemical Formula (5) described below, a divalent organic group represented by Chemical Formula (6) described below, divalent organic groups represented by General Formula (7) described below, and divalent organic groups represented by General Formula (8) described below,

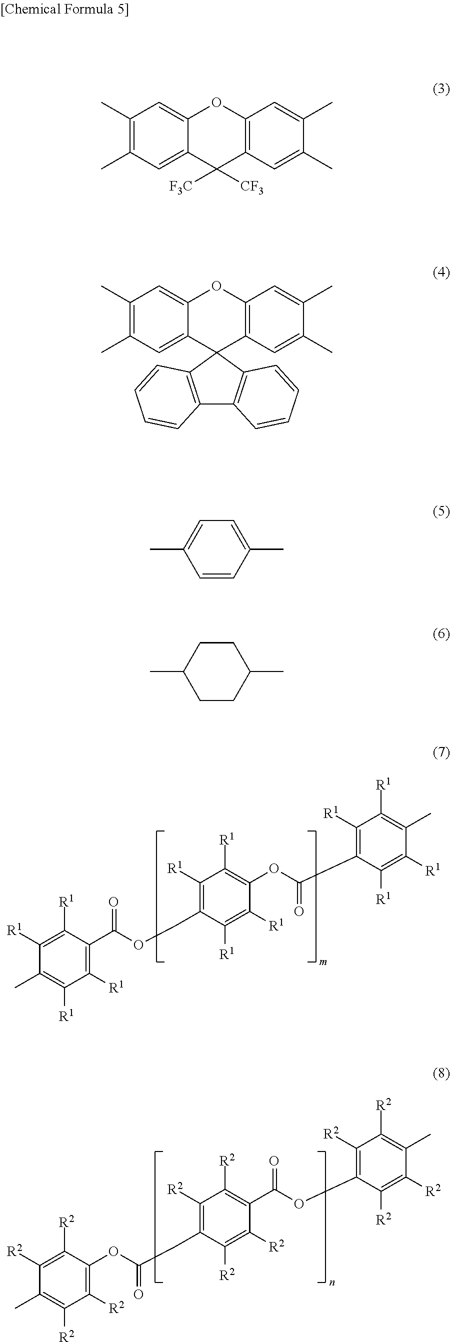

in which R¹ and R² each independently represent a monovalent organic group having 1 or more and 12 or less carbon atoms or represent a hydrogen atom, a plurality of R¹s are optionally equal to or different from each other, a plurality of R²s are optionally equal to or different from each other, and m and n each independently represent an integer of 0 or more and 3 or less, the polyimide film having a linear thermal expansion coefficient of 30 ppm/K or less.
[7] The polyimide film according to [6], in which a content of one or more residues selected from the group consisting of the divalent organic group represented by Chemical Formula (5), the divalent organic group represented by Chemical Formula (6), the divalent organic groups represented by General Formula (7), and the divalent organic groups represented by General Formula (8) is 50 mol % or more and 100 mol % or less with respect to a total amount of diamine residues in the polyimide,
   in General Formula (2), X further includes one or more selected from the group consisting of a tetravalent organic group represented by Chemical Formula (9) described below, a tetravalent organic group represented by Chemical Formula (10) described below, a tetravalent organic group represented by Chemical Formula (11) described below, a tetravalent organic group represented by Chemical Formula (12) described below, and a tetravalent organic group represented by Chemical Formula (13) described below, and
   a content of one or more residues selected from the group consisting of the tetravalent organic group represented by Chemical Formula (9), the tetravalent organic group represented by Chemical Formula (10), the tetravalent organic group represented by Chemical Formula (11), the tetravalent organic group represented by Chemical Formula (12), and the tetravalent organic group represented by Chemical Formula (13) is 5 mol % or more and 95 mol % or less with respect to a total amount of tetracarboxylic dianhydride residues in the polyimide.

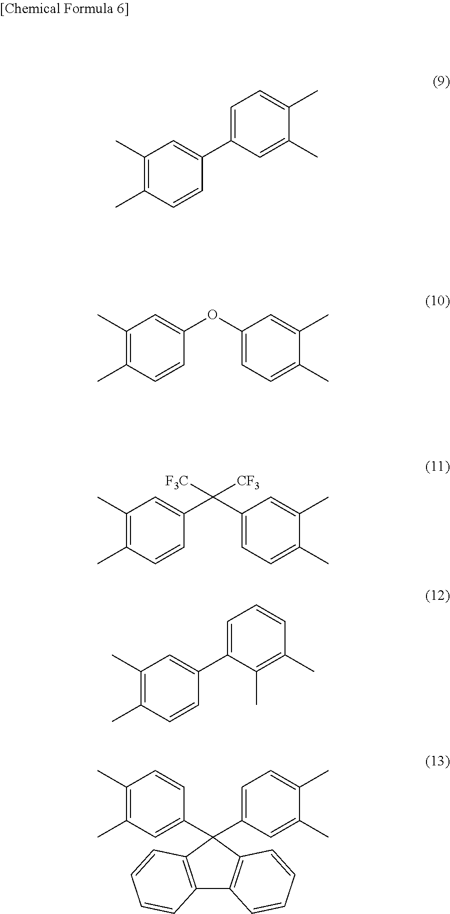

[8] The polyimide film according to [6] or [7], having a haze of 1.0% or less.
[9] A laminate including a support and the polyimide film according to any one of [6] to [8].
[10] An electronic device including the polyimide film according to any one of [6] to [8] and an electronic element disposed on the polyimide film.
[11] An electronic device including the laminate according to [9] and an electronic element disposed on the polyimide film of the laminate.
[12] A method of producing a laminate including a support and a polyimide film, the method including:
   a step Sa of applying the polyimide precursor composition according to any one of [1] to [5] onto a support to form a coating film containing the polyimide precursor; and
   a step Sb of heating the coating film obtained in the step Sa and thus imidizing the polyimide precursor to form a polyimide film on the support.
[9] A method of producing a polyimide film, the method including:
   forming a laminate including a support and a polyimide film with the method according to [12]; and
   peeling the polyimide film from the support.
[14] A method of producing an electronic device, the method including:
   forming a laminate including a support and a polyimide film with the method according to [12]; and
   forming an electronic element on the polyimide film.

A polyimide produced using the polyimide precursor composition according to one or more embodiments of the present invention can reduce the CTE while enhancing the transparency. Therefore, the polyimide produced using the polyimide precursor composition according to one or more embodiments of the present invention is suitable as a material, for an electronic device, required to have transparency and capable of reducing internal stress.

### DETAILED DESCRIPTION

One or more embodiments of the present invention will be described in detail below, but the present invention is not limited to these embodiments. The academic documents and the patent documents mentioned in the present description are incorporated in the present description by reference in their entirety.

First, terms used in the present description will be described. The term “structural unit” refers to a repeating unit included in a polymer. The term “polyamic acid” refers to a polymer that includes a structural unit represented by General Formula (14) described below (hereinafter, sometimes described as “structural unit (14)”) and has an imidization ratio of 0 mol %. The method of measuring the “imidization ratio” is the same as or similar to the method in Examples described below.

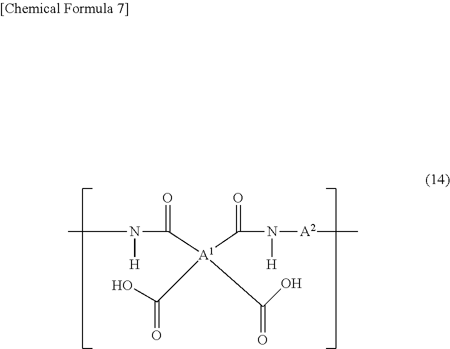

In General Formula (14), A¹ represents a tetracarboxylic dianhydride residue (tetravalent organic group derived from a tetracarboxylic dianhydride), and A² represents a diamine residue (divalent organic group derived from a diamine).

The term “polyimide precursor” refers to a polymer including the structural unit (14) and a structural unit represented by General Formula (15) described below (hereinafter, sometimes described as “structural unit (15)”). The structural unit (15) is a structural unit in which an amide group in the structural unit (14) is imidized. Therefore, A¹ in General Formula (15) represents the same as A¹ in General Formula (14), and A² in General Formula (15) represents the same as A² in General Formula (14).

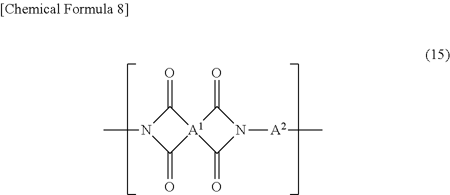

The total content of the structural unit (14) and the structural unit (15) may be 80 mol % or more and 100 mol % or less, 90 mol % or more and 100 mol % or less, 95 mol % or more and 100 mol % or less, or 100 mol %, with respect to the total amount (100 mol %) of the structural units in the polyimide precursor.

The “linear thermal expansion coefficient” is a coefficient of linear thermal expansion during a temperature decrease in the range from 100° C. to 400° C., unless otherwise specified.

Hereinafter, the name of a compound may be followed by the term “-based” to collectively refer to the compound and its derivatives. The term “-based” following the name of a compound to express the name of a polymer means that repeating units of the polymer are derived from the compound or its derivative. The tetracarboxylic dianhydride may be described as “acid dianhydride”. The components, the functional groups, and the like shown in the present description may be used singly or in combination of two or more kinds thereof, unless otherwise specified.

A polyimide precursor composition according to one or more embodiments of the present embodiment contains a polyimide precursor and an organic solvent. The polyimide precursor has a structural unit represented by General Formula (1) described below and a structural unit represented by General Formula (2) described below. Hereinafter, the structural unit represented by General Formula (1) may be described as “structural unit (1)”. The structural unit represented by General Formula (2) may be described as “structural unit (2)”.

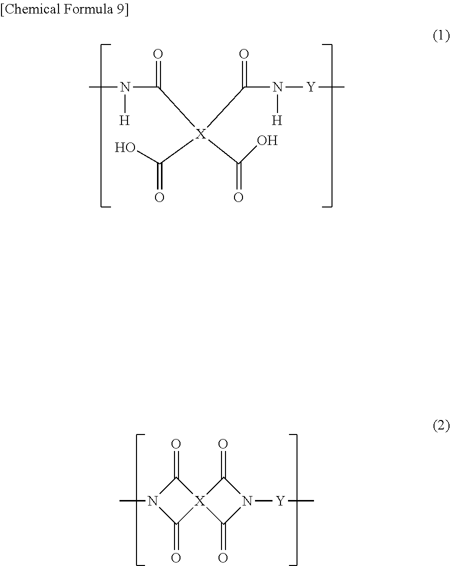

In General Formulas (1) and (2), X includes one or more selected from the group consisting of a tetravalent organic group represented by Chemical Formula (3) described below and a tetravalent organic group represented by Chemical Formula (4) described below, and Y includes one or more selected from the group consisting of a divalent organic group represented by Chemical Formula (5) described below, a divalent organic group represented by Chemical Formula (6) described below, divalent organic groups represented by General Formula (7) described below, and divalent organic groups represented by General Formula (8) described below.

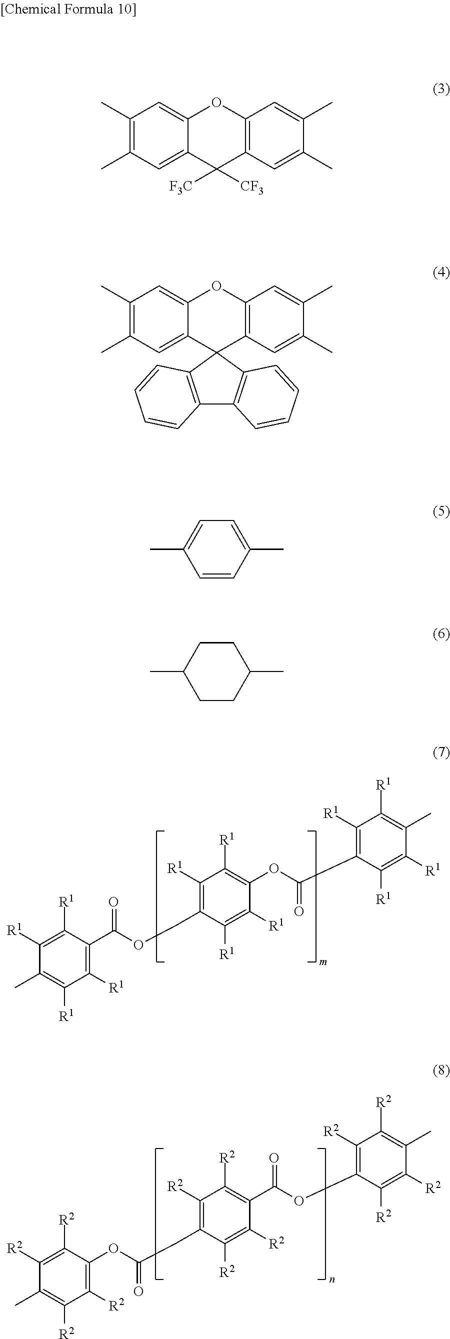

In General Formulas (7) and (8), R¹ and R² each independently represent a monovalent organic group having 1 or more and 12 or less carbon atoms or represent a hydrogen atom, a plurality of R¹s are optionally equal to or different from each other, a plurality of R²s are optionally equal to or different from each other, and m and n each independently represent an integer of 0 or more and 3 or less.

In the polyimide precursor composition according to the present embodiment, the content of the structural unit (2) is 10 mol % or more and less than 80 mol % with respect to the total amount (100 mol %) of the structural units in the polyimide precursor. Hereinafter, the polyimide precursor contained in the polyimide precursor composition according to the present embodiment may be described as “specific polyimide precursor”. The content of the structural unit (2) with respect to the total amount (100 mol %) of the structural units in the polyimide precursor may be described as “imidization ratio”.

A polyimide produced using the polyimide precursor composition according to the present embodiment can reduce the CTE while enhancing the transparency. The reason for this is presumed as follows.

The polyimide precursor composition according to the present embodiment contains the specific polyimide precursor into which a specific xanthene structure is introduced, and therefore when a polyimide is produced, the polyimide has high transparency.

Meanwhile, as described above, when a polyamic acid having the xanthene structure described in Patent Document 4 is used, a polyimide having a relatively large CTE tends to be obtained. In coping with this, the present inventors have found that the specific polyimide precursor obtained by imidizing a part of a polyamic acid having a specific xanthene structure has specifically high solubility in an organic solvent and that the specific polyimide precursor imidized (formed into a film) has a relatively small CTE and can reduce the internal stress when formed into a film on a substrate. It is considered that xanthene structures having the tetravalent organic groups represented by Chemical Formulas (3) and (4) have a side chain having a hexafluoroisopropylidene group or a fluorenyl group and therefore the presence of the specific xanthene structure in a polymer chain improves the solubility and thus can suppress gelation. Furthermore, it is considered that the presence of a xanthene structure having the tetravalent organic group represented by Chemical Formula (3) or (4) in a polymer chain increases the linearity and thus in the partial imidization, the alignment of the polymer chain is dramatically induced to reduce the CTE. Therefore, a polyimide produced using the polyimide precursor composition according to the present embodiment can reduce the CTE.

In the present embodiment, for further reduction of the CTE, the imidization ratio may be 20 mol % or more, 30 mol % or more, 35 mol % or more, 36 mol % or more, 37 mol % or more, 38 mol % or more, 39 mol % or more, or 40 mol % or more.

In the present embodiment, for an improvement in the solubility of the specific polyimide precursor in an organic solvent, the imidization ratio may be 70 mol % or less, 60 mol % or less, 50 mol % or less, or 45 mol % or less.

The tetravalent organic group represented by Chemical Formula (3) is a partial structure (residue) derived from 9,9-bis(trifluoromethyl)-2,3,6,7-xanthene tetracarboxylic dianhydride (hereinafter, sometimes described as “6FCDA”). The tetravalent organic group represented by Chemical Formula (4) is a partial structure (residue) derived from spiro[11H-difuro [3,4-b: 3′,4′-i] xanthene-11,9′-[9H] fluorene]-1,3, 7,9-tetrone (hereinafter, sometimes described as “SFDA”). Therefore, the specific polyimide precursor has one or more tetracarboxylic dianhydride residues selected from the group consisting of 6FCDA residues and SFDA residues.

In the present embodiment, for a further improvement in the transparency, the content of the one or more residues selected from the group consisting of 6FCDA residues and SFDA residues may be 5 mol % or more, 10 mol % or more, 20 mol % or more, 30 mol % or more, 40 mol % or more, or 50 mol % or more, with respect to the total amount (100 mol %) of the tetracarboxylic dianhydride residues in the specific polyimide precursor.

In the specific polyimide precursor, the content of the one or more residues selected from the group consisting of 6FCDA residues and SFDA residues may be 100 mol % with respect to the total amount (100 mol %) of the tetracarboxylic dianhydride residues in the specific polyimide precursor, and the specific polyimide precursor may contain an acid dianhydride residue other than 6FCDA residues and SFDA residues (another acid dianhydride residue). For further reduction of the CTE, the content of the one or more residues selected from the group consisting of 6FCDA residues and SFDA residues may be 95 mol % or less, 90 mol % or less, 80 mol % or less, or 70 mol % or less, with respect to the total amount of the tetracarboxylic dianhydride residues in the specific polyimide precursor.

In order to further reduce the CTE while further enhancing the transparency, the specific polyimide precursor may contain an SFDA residue.

In synthesis of the specific polyimide precursor, an acid dianhydride other than 6FCDA and SFDA may be used as a monomer as long as the performance of the specific polyimide precursor is not impaired. Examples of the acid dianhydride other than 6FCDA and SFDA include 3,3′,4,4′-biphenyltetracarboxylic dianhydride (hereinafter, sometimes described as “BPDA”), 4,4′-oxydiphthalic anhydride (hereinafter, sometimes described as “ODPA”), 4,4′-(hexafluoroisopropylidene)diphthalic anhydride (hereinafter, sometimes described as “6FDA”), 2,3,3′,4′-biphenyltetracarboxylic dianhydride (hereinafter, sometimes described as “a-BPDA”), 9,9-bis(3,4-dicarboxyphenyl) fluorene dianhydride (hereinafter, sometimes described as “BPAF”), pyromellitic dianhydride (hereinafter, sometimes described as “PMDA”), 1,2,5,6-naphthalenetetracarboxylic dianhydride, 2,3,6,7-naphthalenetetracarboxylic dianhydride (hereinafter, sometimes described as “NTCDA”), p-phenylenebis(trimellitate anhydride), 2,2′,3,3′-biphenyltetracarboxylic dianhydride, 3,3′,4,4′-benzophenone tetracarboxylic dianhydride, dicyclohexyl-3,3′,4,4′-tetracarboxylic dianhydride, 1,2,4,5-cyclohexanetetracarboxylic dianhydride, 1,2,3,4-cyclobutanetetracarboxylic dianhydride, 2′-oxodispiro[bicyclo[2.2.1]heptane-2,1′-cyclopentane-3′,2″-bicyclo[2.2.1]heptane]-5,6: 5″,6″-tetracarboxylic dianhydride, and derivatives thereof, and these may be used singly or in combination of two or more kinds thereof.

Among them, PMDA, BPDA, and NTCDA have high linearity and are effective in reducing the CTE, BPAF, 6FDA, and a-BPDA are effective in improving the solubility, and ODPA may be preferable from the viewpoint of increasing the mechanical strength. One or more selected from the group consisting of BPDA, ODPA, 6FDA, a-BPDA, and BPAF may be preferable. That is, the specific polyimide precursor may contain another acid dianhydride residue that is one or more residues selected from the group consisting of a BPDA residue, an ODPA residue, a 6FDA residue, an a-BPDA residue, and a BPAF residue.

In order to further reduce the CTE while further enhancing the transparency, the content of the one or more residues selected from the group consisting of a BPDA residue, an ODPA residue, a 6FDA residue, an a-BPDA residue, and a BPAF residue may be 5 mol % or more and 95 mol % or less, 5 mol % or more and 90 mol % or less, 5 mol % or more and 80 mol % or less, 5 mol % or more and 70 mol % or less, 5 mol % or more and 60 mol % or less, or 5 mol % or more and 50 mol % or less, with respect to the total amount of the tetracarboxylic dianhydride residues in the specific polyimide precursor. In order to further reduce the CTE while further enhancing the transparency, the specific polyimide precursor may contain another acid dianhydride residue that is one or more residues selected from the group consisting of a BPDA residue, an ODPA residue, and a 6FDA residue.

The BPDA residue is a tetravalent organic group represented by Chemical Formula (9) described below. The ODPA residue is a tetravalent organic group represented by Chemical Formula (10) described below. The 6FDA residue is a tetravalent organic group represented by Chemical Formula (11) described below. The a-BPDA residue is a tetravalent organic group represented by Chemical Formula (12) described below. The BPAF residue is a tetravalent organic group represented by Chemical Formula (13) described below.

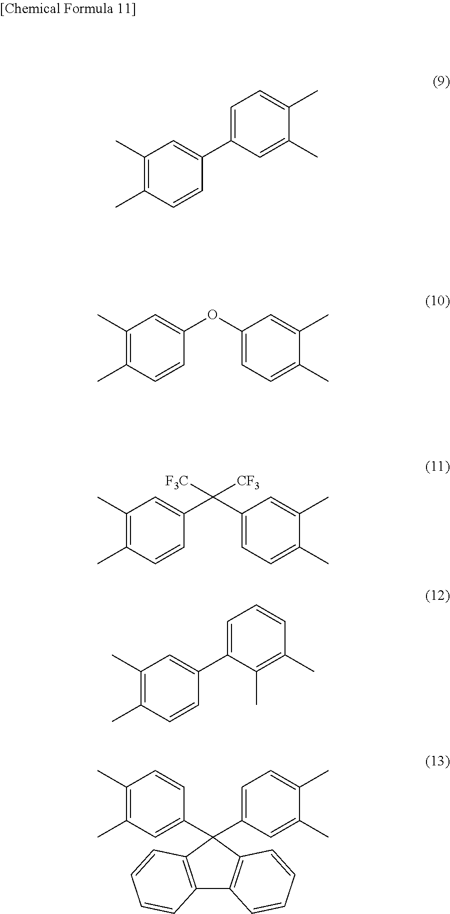

As described above, the specific polyimide precursor contains one or more diamine residues that are represented by Y in the structural units (1) and (2) and selected from the group consisting of the divalent organic group represented by Chemical Formula (5), the divalent organic group represented by Chemical Formula (6), the divalent organic groups represented by General Formula (7), and the divalent organic groups represented by General Formula (8). The above-described specific diamine residues have high linearity, and therefore contribute to reducing the CTE. Hereinafter, the divalent organic groups represented by General Formula (7) may be described as “diamine residues (7)”. The divalent organic groups represented by General Formula (8) may be described as “diamine residues (8)”.

The divalent organic group represented by Chemical Formula (5) is a partial structure (residue) derived from p-phenylenediamine (hereinafter, sometimes described as “PDA”). The divalent organic group represented by Chemical Formula (6) is a partial structure (residue) derived from trans-1,4-cyclohexanediamine (hereinafter, sometimes described as “CHDA”).

In order to further reduce the CTE, the specific polyimide precursor may have one or more diamine residues selected from the group consisting of the diamine residues (7) and the diamine residues (8), or may have a diamine residue (7). The diamine residue (7) may be one or more diamine residues selected from the group consisting of a diamine residue derived from 4-aminophenyl-4-aminobenzoate (hereinafter, sometimes described as “4-BAAB”) and a diamine residue derived from (2-phenyl-4-aminophenyl)-4-aminobenzoate (hereinafter, sometimes described as “PHBAAB”). That is, in order to further reduce the CTE, the specific polyimide precursor may have one or more diamine residues selected from the group consisting of a 4-BAAB residue and a PHBAAB residue. In order to particularly reduce the CTE, the specific polyimide precursor may have a 4-BAAB residue.

In synthesis of the specific polyimide precursor, a diamine other than PDA, CHDA, diamines for formation of the diamine residues (7), and diamines for formation of the diamine residues (8) may be used as a monomer as long as the performance of the specific polyimide precursor is not impaired. Examples of the diamine other than PDA, CHDA, diamines for formation of the diamine residues (7), and diamines for formation of the diamine residues (8) include 9,9-bis(4-aminophenyl) fluorene (hereinafter, sometimes described as “BAFL”), 2,2′-bis(trifluoromethyl)-4,4′-diaminodiphenyl ether (hereinafter, sometimes described as “6FODA”), 4,4′-diaminodiphenyl sulfone (hereinafter, sometimes described as “DDS”), 4,4′-diaminobenzanilide (hereinafter, sometimes described as “DABA”), 1,3-bis(3-aminopropyl)tetramethyldisiloxane (hereinafter, sometimes described as “PAM-E”), m-phenylenediamine, 4,4′-oxydianiline, 3,4′-oxydianiline, N,N′-bis(4-aminophenyl) terephthalamide, m-tolidine, o-tolidine, 4,4′-bis(4-aminophenoxy) biphenyl, 2-(4-aminophenyl)-6-aminobenzoxazole, 3,5-diaminobenzoic acid, 4,4′-diamino-3,3′-dihydroxybiphenyl, 4,4′-methylenebis(cyclohexanamine), and derivatives thereof, and these may be used singly or in combination of two or more kinds thereof.

Among these, BAFL, 6FODA, and DDS can improve the solubility, DABA is effective in reducing the CTE, and PAM-E can enhance the adhesion to a substrate.

In order to further reduce the CTE while further enhancing the transparency, the content of one or more residues selected from the group consisting of a PDA residue, a CHDA residue, the diamine residues (7), and the diamine residues (8) may be 50 mol % or more and 100 mol % or less, 60 mol % or more and 100 mol % or less, 70 mol % or more and 100 mol % or less, 80 mol % or more and 100 mol % or less, or 90 mol % or more and 100 mol % or less, with respect to the total amount (100 mol %) of the diamine residues in the specific polyimide precursor.

In order to further reduce the CTE while further enhancing the transparency, the specific polyimide precursor may satisfy the following condition 1, the following condition 2, or the following condition 3.
Condition 1: The imidization ratio is 20 mol % or more and 60 mol % or less.
Condition 2: The condition 1 is satisfied, and the specific polyimide precursor has an SFDA residue as an acid dianhydride residue.

Condition 3: The condition 2 is satisfied, and the specific polyimide precursor has a 4-BAAB residue as a diamine residue.

The specific polyimide precursor is obtained by partially imidizing a polyamic acid having a specific structure (hereinafter, sometimes described as “polyamic acid (1)”). The polyamic acid (1) can be synthesized with a known general method, and can be obtained, for example, by reacting a diamine with a tetracarboxylic dianhydride in an organic solvent. An example of a specific synthesis method of the polyamic acid (1) will be described. First, in an atmosphere of an inert gas such as argon or nitrogen, a diamine is dissolved or dispersed in a slurry form in an organic solvent to prepare a diamine solution. Then, a tetracarboxylic dianhydride in a state of being dissolved or dispersed in a slurry form in an organic solvent, or a tetracarboxylic dianhydride in a solid state is added to the diamine solution.

In the case of synthesizing a polyamic acid (1) using a diamine and a tetracarboxylic dianhydride, a desired polyamic acid (1) (polymer of a diamine and a tetracarboxylic dianhydride) can be obtained by adjusting the substance amount of the diamine (substance amount of each diamine in a case where a plurality of diamines are used) and the substance amount of the tetracarboxylic dianhydride (substance amount of each tetracarboxylic dianhydride in a case where a plurality of tetracarboxylic dianhydrides are used). The molar fraction of each residue in the polyamic acid (1) is equal to, for example, the molar fraction of each monomer (each of the diamines and the tetracarboxylic dianhydrides) used for synthesis of the polyamic acid (1). A polyamic acid (1) containing a plurality of tetracarboxylic dianhydride residues and a plurality of diamine residues can also be obtained by blending two polyamic acids. The temperature condition for the reaction of the diamine with the tetracarboxylic dianhydride, that is, the synthesis reaction of the polyamic acid (1) is not particularly limited, and is, for example, in the range of 20° C. or higher and 150° C. or lower. The reaction time for the synthesis reaction of the polyamic acid (1) is, for example, in the range of 10 minutes or more and 30 hours or less.

The organic solvent used for synthesis of the polyamic acid (1) may be a solvent capable of dissolving the tetracarboxylic dianhydride and the diamine to be used, or a solvent capable of dissolving the polyamic acid (1) to be generated. Examples of the organic solvent used for synthesis of the polyamic acid (1) include urea-based solvents such as tetramethylurea and N,N-dimethylethylurea; sulfoxide-based solvents such as dimethyl sulfoxide; sulfone-based solvents such as diphenyl sulfone and tetramethyl sulfone; amide-based solvents such as N,N-dimethylacetamide (DMAC), N,N-dimethylformamide (DMF), N,N-diethylacetamide, N-methyl-2-pyrrolidone (NMP), 1-butyl-2-pyrrolidone, 3-methoxy-N,N-dimethylpropanamide (MPA), 3-butoxy-N,N-dimethylpropanamide, N,N-dimethylpropionamide, N,N-diethylformamide, 1,3-dimethyl-2-imidazolidinone, and hexamethylphosphoric triamide; ester-based solvents such as y-butyrolactone; alkyl halide-based solvents such as chloroform and methylene chloride; aromatic hydrocarbon-based solvents such as benzene and toluene; phenol-based solvents such as phenol and cresol; ketone-based solvents such as cyclopentanone; and ether-based solvents such as tetrahydrofuran, 1,3-dioxolane, 1,4-dioxane, dimethyl ether, diethyl ether, diethylene glycol diethyl ether, diethylene glycol dimethyl ether, and p-cresol methyl ether. These solvents are normally used singly, and if necessary, may be appropriately used in combination of two or more kinds thereof. In order to enhance the solubility and the reactivity of the polyamic acid (1), the organic solvent used in the synthesis reaction of the polyamic acid (1) may be one or more solvents selected from the group consisting of amide-based solvents, ketone-based solvents, ester-based solvents, and ether-based solvents, may be an amide-based solvent, or may be one or more solvents selected from the group consisting of NMP, MPA, 1-butyl-2-pyrrolidone, 3-butoxy-N,N-dimethylpropanamide, N,N-dimethylpropionamide, N,N-diethylformamide, and 1,3-dimethyl-2-imidazolidinone. The synthesis reaction of the polyamic acid (1) may be performed under an atmosphere of an inert gas such as argon or nitrogen.

The polyimide precursor composition according to the present embodiment contains the specific polyimide precursor and an organic solvent. In order to enhance the solubility of the specific polyimide precursor, the organic solvent may be a solvent listed as the organic solvent used in the synthesis reaction of the polyamic acid (1). That is, the organic solvent in the polyimide precursor composition according to the present embodiment may be one or more solvents selected from the group consisting of amide-based solvents, ketone-based solvents, ester-based solvents, and ether-based solvents, may be an amide-based solvent, or may be one or more solvents selected from the group consisting of NMP, MPA, 1-butyl-2-pyrrolidone, 3-butoxy-N,N-dimethylpropanamide, N,N-dimethylpropionamide, N,N-diethylformamide, and 1,3-dimethyl-2-imidazolidinone. The content of the specific polyimide precursor in the polyimide precursor composition according to the present embodiment is not particularly limited, and is, for example, 1 wt % or more and 80 wt % or less, 5 wt % or more and 50 wt % or less, or 5 wt % or more and 30 wt % or less with respect to the total amount of the polyimide precursor composition.

The polyimide precursor composition according to the present embodiment may be prepared (partially imidized) from a solution containing the polyamic acid (1) and an organic solvent (polyamic acid solution). Examples of the organic solvent contained in the polyamic acid solution include the organic solvents included in examples of the organic solvent usable for the synthesis reaction of the polyamic acid (1). In the case of obtaining the polyamic acid (1) with the above-described method, the reaction solution (solution after the reaction) itself may be used as a polyamic acid solution for preparation of the polyimide precursor composition. Alternatively, the solid polyamic acid (1) obtained by removing the solvent from the reaction solution may be dissolved in an organic solvent to prepare a polyamic acid solution.

A polyamic acid is usually hydrolyzed due to the influence of moisture or the like, and the resulting decrease in molecular weight causes a change in viscosity, and therefore a polyamic acid solution is desirably stored at about −20° C. In contrast, a part of the polyamic acid (1) is partially imidized, and thus the polyimide precursor composition according to the present embodiment is less likely to be affected by hydrolysis and can be stably stored even at room temperature. Therefore, the polyimide precursor composition according to the present embodiment can reduce the cost at the time of storage and the cost at the time of transportation.

The method of partially imidizing the polyamic acid (1) is not particularly limited, and a known method can be used to perform the partial imidization. Specific methods of the partial imidization include a thermal method, a chemical method, and a method in which a raw material imidized in advance is used to obtain a partially imidized specific polyimide precursor. From the viewpoint of controlling the imidization ratio within the above-described predetermined range, a method of the partial imidization with a chemical method (chemical imidization method) may be preferable. A by-product such as a tertiary amine generated with the chemical imidization method or the like may be formed into a film while remaining in the polyimide precursor composition, or such a by-product may be separated by reprecipitating the specific polyimide precursor in a poor solvent and then the specific polyimide precursor may be dissolved in an organic solvent again to obtain a polyimide precursor composition.

Examples of the chemical imidization method include a method in which one or more selected from the group consisting of imidization catalysts and dehydration catalysts are added to a polyamic acid solution containing the polyamic acid (1) to partially imidize the polyamic acid (1). The temperature condition for the partial imidization of the polyamic acid (1) is, for example, in the range of 20° C. or higher and 150° C. or lower. The reaction time for the partial imidization of the polyamic acid (1) is, for example, in the range of 10 minutes or more and 30 hours or less. The imidization ratio can be adjusted, for example, by changing at least one of the amount of the imidization catalyst, the amount of the dehydration catalyst, the temperature condition for the partial imidization, or the reaction time for the partial imidization.

The imidization catalyst is not particularly limited, and a tertiary amine can be used. The tertiary amine may be a heterocyclic tertiary amine. Examples of the heterocyclic tertiary amine include pyridine, picoline, lutidine, ethylpyridine, diethylpyridine, isoquinoline, and 1,2-dimethylimidazole. The dehydration catalyst is not particularly limited, and examples of the dehydration catalyst include acetic anhydride, propionic anhydride, n-butyric anhydride, benzoic anhydride, and trifluoroacetic anhydride.

The amount of the imidization catalyst added may be 0.1 times molar equivalent or more and 1.5 times molar equivalent or less, 0.2 times molar equivalent or more and 1.0 times molar equivalent or less, or 0.3 times molar equivalent or more and 0.8 times molar equivalent or less with respect to the amide group in the polyamic acid (1). The amount of the dehydration catalyst added may be 0.1 times molar equivalent or more and 0.9 times molar equivalent or less, 0.1 times molar equivalent or more and 0.8 times molar equivalent or less, 0.2 times molar equivalent or more and 0.7 times molar equivalent or less, or 0.3 times molar equivalent or more and 0.6 times molar equivalent or less with respect to the amide group in the polyamic acid (1). When added to the polyamic acid solution, the imidization catalyst and/or the dehydration catalyst may be directly added without being dissolved in an organic solvent, or may be dissolved in an organic solvent and then the resulting solution may be added. In the method of direct addition without dissolution in an organic solvent, the reaction may rapidly proceed before diffusion of the imidization catalyst and/or the dehydration catalyst, resulting in generation of a gel. Therefore, a solution obtained by dissolving the imidization catalyst and/or the dehydration catalyst in an organic solvent may be mixed with the polyamic acid solution.

In the case of obtaining a specific polyimide precursor partially imidized using a raw material imidized in advance, the raw material imidized in advance may be one or more selected from the group consisting of diamines represented by General Formula (16) described below and acid dianhydrides represented by General Formula (17) described below. Specific examples of the diamines represented by General Formula (16) include a diamine represented by Chemical Formula (18) described below. Specific examples of the acid dianhydrides represented by General Formula (17) include an acid dianhydride represented by Chemical Formula (19) described below. Incorporating the SFDA structure or the 6FCDA structure into the raw material imidized in advance can enhance the linearity and the solubility of the molecular chain, and as a result, further reduction of the CTE can be realized. Such a raw material imidized in advance can be synthesized with a thermal imidization method or a chemical imidization method using two or more equivalents of a diamine or an acid dianhydride with respect to the acid dianhydride or the diamine in the raw material. The raw material can also be obtained with a method in which a nitro group-containing amine such as nitroaniline is reacted with an acid dianhydride, then the reaction product is imidized with a thermal imidization method or a chemical imidization method, and then the nitro group is reduced.

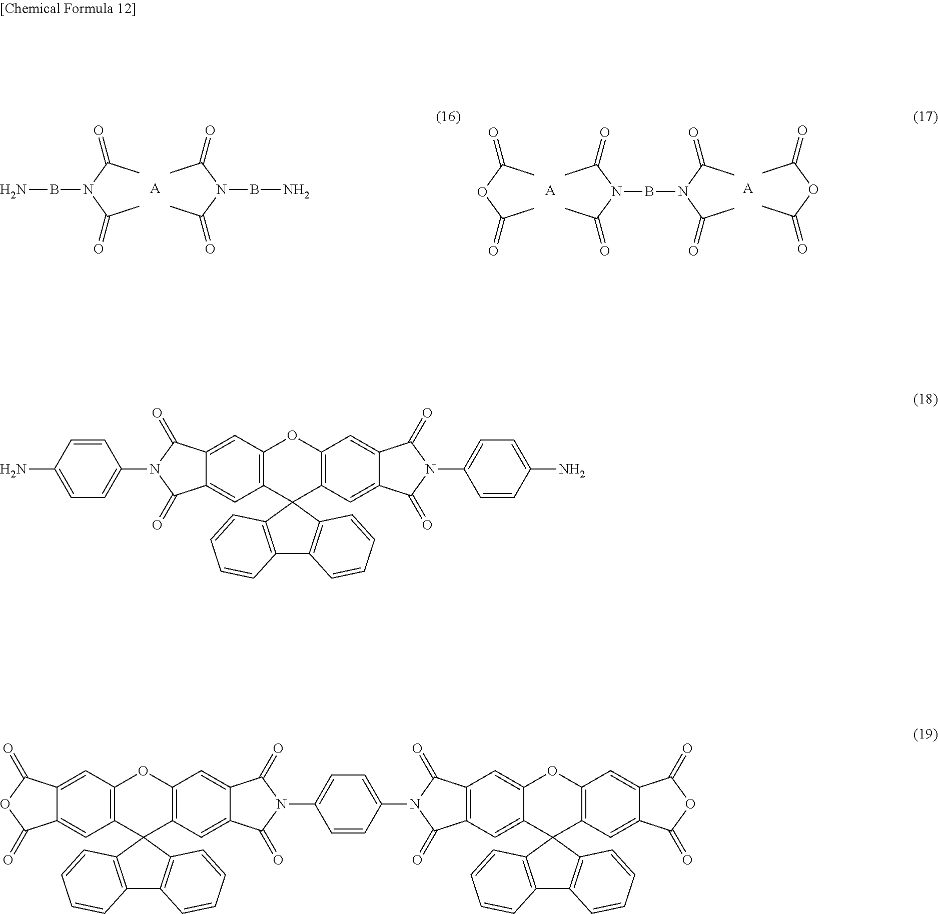

In General Formulas (16) and (17), each A independently represents a tetravalent organic group, and each B independently represents a divalent organic group.

The weight average molecular weight of the specific polyimide precursor may be in the range of 10,000 or more and 1,000,000 or less, in the range of 20,000 or more and 500,000 or less, or in the range of 30,000 or more and 200,000 or less although depending on the use of the specific polyimide precursor. If the weight average molecular weight is 10,000 or more, the viscosity of the polyimide precursor composition can be easily adjusted to a range suitable for application (for example, 0.5 Pa's or more and 10 Pa's or less). Meanwhile, if the weight average molecular weight is 1,000,000 or less, the specific polyimide precursor exhibits sufficient solubility in a solvent, and therefore a coating film or a polyimide film having a smooth surface and a uniform thickness can be obtained using the polyimide precursor composition described below. The weight average molecular weight used herein refers to a value in terms of polyethylene oxide measured using gel permeation chromatography (GPC).

Examples of a method of controlling the molecular weight of the specific polyimide precursor include a method in which an acid dianhydride or a diamine is excessively used, and a method in which a monofunctional acid anhydride or a monofunctional amine, such as phthalic anhydride or aniline, is reacted to quench the reaction. In a case where an acid dianhydride or a diamine is excessively used for polymerization, a polyimide film having sufficient strength can be obtained as long as the molar ratio of the diamine to the acid dianhydride for preparation is in the range from 0.95 to 1.05. The above-described molar ratio of the diamine to the acid dianhydride for preparation is the ratio of the total substance amount of the diamine used for synthesis of the specific polyimide precursor to the total substance amount of the acid dianhydride used for synthesis of the specific polyimide precursor (total substance amount of diamine/total substance amount of acid dianhydride). It is also possible to use phthalic anhydride, maleic anhydride, aniline, or the like for end-capping to further reduce coloring of the polyimide obtained using the specific polyimide precursor.

In the polyimide precursor composition according to the present embodiment, various organic or inorganic low molecular weight compounds or polymer compounds may be blended as additives. Examples of a usable additive include a plasticizer, an antioxidant, a dye, a surfactant, a leveling agent, silicone, fine particles, and a sensitizer. The fine particles include organic fine particles including polystyrene and polytetrafluoroethylene, and inorganic fine particles including colloidal silica, carbon, and layered silicate, and may have a porous structure or a hollow structure. The function and the form of the fine particles are not particularly limited, and may be, for example, a pigment, a filler, or fibrous particles.

The polyimide precursor composition according to the present embodiment can contain a silane coupling agent in order to develop appropriate adhesion to a support. Although a known silane coupling agent can be used without particular limitation, a compound containing an amino group may be preferable from the viewpoint of reactivity with the specific polyimide precursor.

The ratio of the silane coupling agent blended to 100 parts by weight of the specific polyimide precursor may be 0.01 parts by weight or more and 0.50 parts by weight or less, 0.01 parts by weight or more and 0.10 parts by weight or less, or 0.01 parts by weight or more and 0.05 parts by weight or less. If the ratio of the silane coupling agent blended is 0.01 parts by weight or more, the effect of suppressing peeling from a support is sufficiently exhibited, and if the ratio of the silane coupling agent blended is 0.50 parts by weight or less, a decrease in the molecular weight of the specific polyimide precursor is suppressed, so that embrittlement of the polyimide film can be suppressed.

The polyimide film according to the present embodiment is obtained by imidizing (completely imidizing) the specific polyimide precursor in the polyimide precursor composition according to the present embodiment. Therefore, the polyimide film according to the present embodiment is a polyimide film containing a polyimide having the structural unit (2). The preferred configuration (the kind of each residue, the content of each residue, and the like) of the structural unit (2) may be the same as the preferred configuration of the structural unit (2) of the specific polyimide precursor described above. The polyimide film according to the present embodiment can be obtained by a known method, and the method of producing the polyimide film is not particularly limited. Hereinafter, an example of a method will be described in which the specific polyimide precursor is imidized to obtain the polyimide film according to the present embodiment. The imidization is performed by subjecting the specific polyimide precursor to cyclodehydration. The cyclodehydration can be performed with an azeotropic method using an azeotropic solvent, a thermal method, or a chemical method.

The cyclodehydration of the specific polyimide precursor may be performed by heating the specific polyimide precursor. The method of heating the specific polyimide precursor is not particularly limited, and for example, a method may be used in which the polyimide precursor composition according to the present embodiment described above is applied onto a support such as a glass substrate, a metal plate, or a polyethylene terephthalate film (PET film) and then the specific polyimide precursor is heat-treated at a temperature in the range of 40° C. or higher and 500° C. or lower. This method provides a laminate according to the present embodiment including a support and a polyimide film (specifically, a polyimide film containing an imidized product of the specific polyimide precursor) disposed on the support. The heating time in imidization depends on the amount of the specific polyimide precursor treated in cyclodehydration and the heating temperature, but the heating time may be in the range of 1 minute or more and 300 minutes or less after the treatment temperature reaches the maximum temperature.

The polyimide film according to the present embodiment is obtained using the polyimide precursor composition according to the present embodiment, and therefore the polyimide film has high transparency and a low CTE. The polyimide film according to the present embodiment may have a CTE of 30 ppm/K or less, or 28 ppm/K or less. The method of measuring the CTE is the same as or similar to the method in Examples described below. The lower limit of the CTE of the polyimide film according to the present embodiment is not particularly limited, and is, for example, 10 ppm/K or more.

The polyimide film (specifically, polyimide film containing an imidized product of the specific polyimide precursor) according to the present embodiment is colorless and transparent and has a low yellowness index and a glass transition temperature (heat resistance) to be resistant to a step of preparing a thin film transistor (TFT), and therefore is suitable for a transparent substrate material of a flexible display. The content of the polyimide (specifically, imidized product of the specific polyimide precursor) in the polyimide film according to the present embodiment may be, for example, 70 wt % or more, 80 wt % or more, 90 wt % or more, or 100 wt % with respect to the total amount of the polyimide film. Examples of the component other than the polyimide in the polyimide film include the above-described additives (more specifically, fine particles and the like).

An electronic device (more specifically, flexible device or the like) according to the present embodiment includes the polyimide film according to the present embodiment and an electronic element directly or indirectly disposed on the polyimide film. The electronic device (more specifically, flexible device or the like) according to the present embodiment may be an electronic device that includes a laminate including a support and a polyimide film (specifically, a polyimide film containing an imidized product of the specific polyimide precursor) and includes an electronic element directly or indirectly disposed on the polyimide film of the laminate. In the case of producing the electronic device according to the present embodiment for a flexible display, first, a polyimide film is formed on an inorganic substrate such as glass as a support. Then, an electronic element such as a TFT is disposed (formed) on the polyimide film to form an electronic device on the support. The step of forming a TFT is generally performed in a wide temperature range of 150° C. or higher and 650° C. or lower, and in order to actually achieve desired performance, an oxide semiconductor layer or an a-Si layer is formed at 300° C. or higher, and in some cases, a-Si or the like is further crystallized with a laser or the like.

At this time, if the polyimide film has a low thermal decomposition temperature, outgassing occurs during formation of an electronic element, and a sublimate may adhere to the inside of the oven to cause contamination in the furnace, or an inorganic film (a barrier film or the like described below) formed on the polyimide film or the electronic element may be peeled off. Therefore, the polyimide may have a 1% weight loss temperature of 500° C. or higher. The upper limit of the 1% weight loss temperature of the polyimide may be as high as possible, and is, for example, 600° C. The 1% weight loss temperature can be adjusted, for example, by changing the content of a residue having a rigid structure (more specifically, for example, a BPDA residue). More specifically, before forming a TFT, an inorganic film such as a silicon oxide film (SiOx film) or a silicon nitride film (SiNx film) is formed as a barrier film on the polyimide film. At this time, if the polyimide has low heat resistance, or progress of imidization is incomplete, or the amount of the residual solvent is large, a volatile component such as a decomposition gas of the polyimide may cause peeling of the polyimide and the inorganic film in a high-temperature process after layering of the inorganic film. Therefore, it is desirable that the polyimide has a 1% weight loss temperature of 500° C. or higher and that the polyimide isothermally held at a temperature in the range of 400° C. or higher and 450° C. or lower has a weight loss ratio of less than 1%.

If the polyimide has a glass transition temperature (Tg) significantly lower than the process temperature, positional deviation or the like may occur during formation of an electronic element. Therefore, the polyimide may have a Tg of 300° C. or higher, 350° C. or higher, 400° C. or higher, or 420° C. or higher. The upper limit of the Tg of the polyimide may be as high as possible, and is, for example, 470° C. Furthermore, an internal stress is generated between the glass substrate and the polyimide film because a glass substrate generally has a smaller linear thermal expansion coefficient (CTE) than a resin. If the internal stress is high in the laminate including the glass substrate used as a support, the electronic element, and the polyimide film, after the laminate including the polyimide film expands in the high-temperature TFT forming step, the laminate contracts when cooled to normal temperature to cause outcomes such as warpage and breakage of the glass substrate and peeling of the polyimide film from the glass substrate. Therefore, in the laminate (laminate according to the present embodiment) including the glass substrate (support) and the polyimide film, the internal stress between the polyimide film and the glass substrate may be 40 MPa or less, or 35 MPa or less. The lower limit of the internal stress may be as low as possible, or 0 MPa. The method of measuring the internal stress is the same as or similar to the method in Examples described below.

The polyimide according to the present embodiment can be suitably used as a material of a display substrate such as a TFT substrate or a touch panel substrate. In the above-described use of the polyimide, a method is often adopted in which an electronic device (specifically, electronic device in which an electronic element is formed on a polyimide film) is formed on a support as described above, and then the polyimide film is peeled from the support. As a material of the support, alkali-free glass is suitably used. Hereinafter, an example of a method of producing a laminate including a polyimide film and a support will be described in detail.

First, the polyimide precursor composition according to the present embodiment is applied (cast) onto a support to form a coating film-containing laminate that includes a coating film containing the specific polyimide precursor and includes the support (step Sa). Next, the coating film-containing laminate is heated under a condition of, for example, a temperature of 40° C. or higher and 200° C. or lower. The heating time at this time is, for example, 3 minutes or more and 120 minutes or less. A multi-stage heating step may be provided such that the coating film-containing laminate is heated at a temperature of 50° C. for 30 minutes and then heated at a temperature of 100° C. for 30 minutes. Next, in order to advance imidization of the specific polyimide precursor in the coating film, the coating film-containing laminate is heated under a condition of, for example, a maximum temperature of 200° C. or higher and 500° C. or lower (step Sb). The heating time (heating time at the maximum temperature) at this time is, for example, 1 minute or more and 300 minutes or less. At this time, the temperature may be raised gradually from a low temperature to the maximum temperature. The temperature rise rate may be 2° C./min or more and 10° C./min or less, or 4° C./min or more and 10° C./min or less. The maximum temperature may be in the range of 250° C. or higher and 450° C. or lower. If the maximum temperature is 250° C. or higher, imidization sufficiently proceeds, and if the maximum temperature is 450° C. or lower, thermal deterioration and coloring of the polyimide can be suppressed. The temperature may be held at any temperature for any period of time until reaching the maximum temperature. The imidization reaction can be performed under air, under reduced pressure, or in an inert gas such as nitrogen, and in order to develop higher transparency, the imidization reaction may be performed under reduced pressure or in an inert gas such as nitrogen. As a heater, a known device such as a hot-air oven, an infrared oven, a vacuum oven, an inert oven, or a hot plate can be used. Through these steps, the specific polyimide precursor in the coating film is imidized, and a laminate (that is, the laminate according to the present embodiment) can be obtained that includes the support and the polyimide film (film containing an imidized product of the specific polyimide precursor).

As a method of peeling the polyimide film from the obtained laminate including the support and the polyimide film, a known method can be used. For example, the polyimide film may be peeled manually, or may be peeled using a machine such as a drive roll or a robot. Furthermore, a method can be adopted in which a peeling layer is provided between a support and a polyimide film, and a method can be adopted in which a silicon oxide film is formed on a substrate having a large number of grooves, a polyimide film is formed using the silicon oxide film as a base layer, and an etching solution of silicon oxide is infiltrated between the substrate and the silicon oxide film to peel the polyimide film. In addition, a method can be adopted in which the polyimide film is separated by irradiation with laser light.

The transparency of the polyimide film can be evaluated with the total light transmittance (TT) in accordance with JIS K 7361-1:1997 and the haze in accordance with JIS K 7136-2000. In a use of the polyimide film in which high transparency is required, the polyimide film may have a total light transmittance of 75% or more, or 80% or more. In a use of the polyimide film in which high transparency is required, the polyimide film may have a haze of 1.5% or less, 1.2% or less, 1.0% or less, or 0%. In a use in which high transparency is required, the polyimide film is required to have high transmittance in the entire wavelength region, but the polyimide film tends to absorb light on the short wavelength side, and the film itself is often colored yellow. For a use of the polyimide film in which high transparency is required, coloring of the polyimide film may be reduced. Specifically, for a use of the polyimide film in which high transparency is required, the polyimide film may have a yellowness index (YI) of 25 or less, 20 or less, or 0. The YI can be measured in accordance with JIS K 7373-2006. As described above, the polyimide film in which coloring is reduced and transparency is imparted is suitable for a transparent substrate for use as a substitute for glass, or a substrate having a back surface on which a sensor or a camera module is provided.

As described above, in use in which transparency is required, the transmittance of blue light (light having a wavelength of around 470 nm) is particularly required to be high from the viewpoint of color reproducibility and the like, and practically, the transmittance of light having a wavelength of 400 nm (hereinafter, sometimes described as “400 nm transmittance”) is required to be high. From the viewpoint of color reproducibility and the like, the polyimide film may have a 400 nm transmittance of 35% or more, 40% or more, 50% or more, or 60% or more. The upper limit of the 400 nm transmittance of the polyimide film is not particularly limited, and may be 100%.

The light extraction systems of flexible displays are classified into two types: a top emission system that extracts light from the front surface side of a TFT; and a bottom emission system that extracts light from the back surface side of a TFT. The top emission system is characterized in that light is not blocked by the TFT and thus the aperture ratio can be easily increased to obtain high definition image quality, and the bottom emission system is characterized in that alignment between the TFT and the pixel electrode is easy and thus the production is facilitated. If the TFT is transparent, the aperture ratio can be improved even in the bottom emission system, and therefore a large display tends to adopt a bottom emission system, which is easy to produce. The polyimide film according to the present embodiment has a low YI and excellent heat resistance, and therefore can be applied to both of the light extraction systems described above.

In a batch-type device preparation process in which the polyimide precursor composition is applied onto a support such as a glass substrate and imidized by heating, an electronic element or the like is formed, and then the polyimide film is peeled off, the adhesion between the support and the polyimide film may be excellent. The term “adhesion” as used herein means adhesive strength. In a preparation process in which an electronic element or the like is formed on a polyimide film on a support and then the polyimide film on which the electronic element or the like is formed is peeled from the support, if the adhesion between the polyimide film and the support is excellent, the electronic element or the like can be formed or mounted more accurately. In a production process in which an electronic element or the like is disposed on a support via a polyimide film, the peel strength between the support and the polyimide film may be as high as possible from the viewpoint of improving the productivity. Specifically, the peel strength may be 0.05 N/cm or more, or 0.1 N/cm or more.

In a production process as described above, when the polyimide film is peeled from the laminate including the support and the polyimide film, the polyimide film is often peeled from the support by laser irradiation. In this case, the polyimide film needs to absorb the laser light, and therefore the polyimide film is required to have a cut-off wavelength longer than the wavelength of the laser light used for peeling. For laser peeling, a XeCl excimer laser with a wavelength of 308 nm is often used, and therefore the polyimide film may have a cut-off wavelength of 312 nm or more, or 330 nm or more. Meanwhile, the polyimide film having a long cut-off wavelength tends to be colored in yellow, and therefore the polyimide film may have a cut-off wavelength of 390 nm or less. From the viewpoint of achieving both the transparency (low yellowness) and the processability of laser peeling, the polyimide film may have a cut-off wavelength of 320 nm or more and 390 nm or less, or 330 nm or more and 380 nm or less. The cut-off wavelength in the present description means the wavelength at which the transmittance becomes 0.1% or less as measured by an ultraviolet-visible spectrophotometer.

The polyimide precursor composition according to the present embodiment may be used as it is in coating or a molding process for preparation of a product or a member, and can also be used as a material for a further treatment such as coating on a molded product molded into a film shape. For use in coating or a molding process, a composition containing the specific polyimide precursor may be prepared by dissolving or dispersing the polyimide precursor composition in an organic solvent as necessary, and further blending a photocurable component, a thermosetting component, a non-polymerizable binder resin, and another component as necessary.

On a surface of the polyimide film according to the present embodiment, various inorganic thin films may be formed such as a metal oxide thin film and a transparent electrode. The methods of forming these inorganic thin films are not particularly limited, and examples thereof include PVD methods such as a sputtering method, a vacuum vapor deposition method, and an ion plating method, and CVD methods.

In the polyimide film according to the present embodiment, the internal stress generated at the time of forming a laminate with a glass substrate is so small that the adhesion to an inorganic material during a high-temperature process can be ensured in addition to the heat resistance, the low thermal expansion, and the transparency, and therefore the polyimide film may be used in fields and products where these properties are effective. For example, the polyimide film according to the present embodiment may be used in an image display device such as a liquid crystal display device, an organic EL, or an electronic paper, a printed matter, a color filter, a flexible display, an optical film, a 3D display, a touch panel, a transparent conductive film substrate, a solar cell, or the like, and may be used as an alternative material for a portion where glass is currently used. In these uses, the polyimide film may have a thickness of, for example, 1 μm or more and 200 μm or less, or 5 μm or more and 100 μm or less. The thickness of the polyimide film can be measured by using a laser hologage.

The polyimide precursor composition according to the present embodiment can be suitably used in a method of producing a polyimide film, in which the polyimide precursor composition is applied onto a support and imidized by heating and then the polyimide film is peeled from the support. Furthermore, the polyimide precursor composition according to the present embodiment can be suitably used in a batch-type device preparation process in which the polyimide precursor composition is applied onto a support and imidized by heating, an electronic element or the like is formed on the formed polyimide film, and then the polyimide film on which the electronic element or the like is formed is peeled from the support. Therefore, the present embodiment also includes a method of producing a polyimide film, in which a laminate is obtained by the above-described method of producing a laminate according to the present embodiment and then the polyimide film is obtained by peeling the polyimide film from the support. Furthermore, the present embodiment also includes a method of producing an electronic device, in which a laminate is obtained by the above-described method of producing a laminate according to the present embodiment and then an electronic element is formed on the formed polyimide film.

### EXAMPLES

Examples of one or more embodiments of the present invention will be described below, but the scope of the present invention is not limited to the following examples.

### <Methods of Measuring Physical Properties>

First, methods of measuring physical properties of a polyimide (polyimide film) will be described.

### [Yellowness Index (YI)]

For the polyimide film in each laminate obtained in Examples and Comparative Examples described below, the transmittance of light having a wavelength of 200 nm or more and 800 nm or less was measured using an ultraviolet visible near infrared spectrophotometer (“V-650” manufactured by JASCO Corporation), and the yellowness index (YI) of the polyimide film was calculated from the formula described in JIS K 7373-2006.

### [400 nm Transmittance]

For the polyimide film in each laminate obtained in Examples and Comparative Examples described below, the transmittance of light having a wavelength of 400 nm (400 nm transmittance) was measured using an ultraviolet visible near infrared spectrophotometer (“V-650” manufactured by JASCO Corporation).

### [Haze]

For the polyimide film peeled from each laminate obtained in Examples and Comparative Examples described below, the haze was measured with the method described in JIS K 7136-2000 using an integrating sphere haze meter (“HM-150N” manufactured by Murakami Color Research Laboratory). A polyimide film having a haze of 1.0% or less was evaluated as “excellent in transparency”. A polyimide film having a haze of more than 1.0% was evaluated as “not excellent in transparency”.

### [Internal Stress]

Each polyimide precursor composition prepared in Examples described below or each polyamic acid solution prepared in Comparative Examples described below was applied with a spin coater onto a glass substrate manufactured by Corning Incorporated (material: alkali-free glass, thickness: 0.7 mm, size: 100 mm×100 mm) measured in advance to determine the amount of warpage, and the resulting product was heated at 120° C. for 30 minutes in the air, and then heated at 430° C. for 30 minutes in a nitrogen atmosphere to obtain a laminate including a polyimide film having a thickness of 10 μm on the glass substrate. In order to eliminate the influence of water absorption of the polyimide film, the laminate was dried at 120° C. for 10 minutes, and then the amount of warpage of the laminate was measured in a nitrogen atmosphere at a temperature of 25° C. using a thin film stress measuring device (“FLX-2320-S” manufactured by KLA-Tencor Corporation). Then, from the amount of warpage of the glass substrate before formation of the polyimide film and the amount of warpage of the laminate, the internal stress generated between the glass substrate and the polyimide film was calculated with the Stoney equation.

### [Internal Stress Reduction Ratio]

First, the internal stress was measured with the method described in the section of [Internal Stress] using each polyamic acid solution (solution used for preparation of each polyimide precursor composition) prepared in Examples described below. Hereinafter, the value of the internal stress obtained here is described as “internal stress before partial imidization”. Next, the internal stress was measured with the method described in the section of [Internal Stress] using each polyimide precursor composition prepared in Examples described below. Hereinafter, the value of the internal stress obtained here is described as “internal stress after partial imidization”. Then, the internal stress reduction ratio (unit:%) was calculated in accordance with the following formula.

$$Internal stress reduction ratio = 100 \times ( 1 - internal stress after partial imidization / internal stress before partial imidization )$$

The larger the value of the internal stress reduction ratio is, the lower the internal stress is than in the case without partial imidization. The internal stress reduction ratio may be 20% or more, 50% or more, or 80% or more.

### [Linear Thermal Expansion Coefficient (CTE)]

For the polyimide film peeled from each laminate obtained in Examples and Comparative Examples described below, the CTE was measured under the condition of a load of 29.8 mN using a thermal analyzer (“TMA/SS7100” manufactured by Hitachi High-Tech Science Corporation). Specifically, the polyimide film (width: 3 mm, length: 10 mm) was heated in a nitrogen atmosphere from 20° C. to 450° C. under the condition of a temperature rise rate of 10° C./min, and then cooled to 20° C. at a temperature fall rate of 40° C./min, and at this time, the CTE was determined from the amount of strain in the range from 100° C. to 400° C. at the time of temperature fall. A polyimide film having a CTE of 30 ppm/K or less was evaluated as “capable of reducing CTE”. A polyimide film having a CTE of more than 30 ppm/K was evaluated as “incapable of reducing CTE”.

### [Imidization Ratio]

First, each polyimide precursor composition prepared in Examples described below or each polyamic acid solution prepared in Comparative Examples described below was applied onto a glass substrate, heated at 120° C. for 30 minutes in the air, and then heated at 430° C. for 30 minutes in a nitrogen atmosphere to obtain a polyimide film (thickness: 10 μm). Next, each obtained polyimide film was measured with an attenuated total reflection method (ATR method) using a Fourier transform infrared spectrophotometer (“FT/IR-6100” manufactured by JASCO Corporation) to obtain an infrared absorption spectrum. Hereinafter, the infrared absorption spectrum obtained here is described as “IRF”.

Next, each polyimide precursor composition prepared in Examples described below or each polyamic acid solution prepared in Comparative Examples described below was applied onto a glass substrate, and heated at 60° C. for 60 minutes in the air to obtain a film (thickness: 10 μm). Next, each obtained film was measured with an attenuated total reflection method (ATR method) using a Fourier transform infrared spectrophotometer (“FT/IR-6100” manufactured by JASCO Corporation) to obtain an infrared absorption spectrum. Hereinafter, the infrared absorption spectrum obtained here is described as “IR_{V}”. Then, the imidization ratio (unit:mol %) was calculated from the following formula.

$$Imidization ratio = 100 \times ( {V}_{1340} / {V}_{1500} ) / ( {F}_{1340} / {F}_{1500} )$$

V₁₅₀₀: Peak intensity derived from aromatic ring around 1500 cm⁻¹ of IR_{V}
V₁₃₄₀: Peak intensity derived from imide group around 1340 cm⁻¹ of IR_{V}
F₁₅₀₀: Peak intensity derived from aromatic ring around 1500 cm⁻¹ of IRF
F₁₃₄₀: Peak intensity derived from imide group around 1340 cm⁻¹ of IRF

### <Preparation of Polyamic Acid Solution>

Hereinafter, a method of preparing polyamic acid solutions P1 to P6 used in Examples and Comparative Examples will be described. In the following, compounds and reagents are represented by the following abbreviations. All of the polyamic acid solutions P1 to P6 were prepared in a nitrogen atmosphere.
NMP: N-methyl-2-pyrrolidone
BPDA: 3,3′,4,4′-Biphenyltetracarboxylic dianhydride
SFDA: Spiro [11H-difuro [3,4-b: 3′,4′-i] xanthene-11,9′-[9H] fluorene]-1,3, 7,9-tetrone
ODPA: 4,4′-Oxydiphthalic anhydride
4-BAAB: 4-Aminophenyl-4-aminobenzoate
DDS: 4,4′-Diaminodiphenylsulfone
Compound 1: Diamine represented by Chemical Formula (18)
PDA: p-Phenylenediamine
DMI: 1,2-Dimethylimidazole
AC₂O: Acetic anhydride

[Preparation of Polyamic Acid Solution P1]

Into a 300 mL glass separable flask equipped with a stirrer including a stainless steel stirring rod and with a nitrogen inlet tube, 60.0 g of NMP was put as an organic solvent for polymerization. Then, 4.887 g of 4-BAAB was put into the flask and dissolved while the flask contents were stirred. Then, 10.113 g of SFDA was added to the flask contents, and then the flask contents were stirred for 24 hours under an atmosphere at a temperature of 23° C. to obtain a polyamic acid solution P1.

### [Preparation of Polyamic Acid Solutions P2 to P6]

Polyamic acid solutions P2 to P6 were each prepared with the same method as the method of preparing the polyamic acid solution P1, except that the used acid dianhydride, the ratio of each acid dianhydride put into the flask, the used diamine, and the ratio of each diamine put into the flask were changed as shown in Table 1. In all of the polyamic acid solutions P2 to P6, the total substance amount of acid dianhydrides in preparation of the polyamic acid solution was the same as that in the polyamic acid solution P1. In all of the polyamic acid solutions P2 to P6, the total substance amount of diamines in preparation of the polyamic acid solution was the same as that in the polyamic acid solution P1.

For the polyamic acid solutions P1 to P6, Table 1 shows the used acid dianhydride, the ratio of each acid dianhydride put into the flask, the used diamine, and the ratio of each diamine put into the flask. In Table 1, “-” means that the relevant component was not used. In Table 1, the numerical value in the column of “Acid dianhydride” is the content (unit: mol %) of each acid dianhydride to the total amount of acid dianhydrides used. In Table 1, the numerical value in the column of “Diamine” is the content (unit: mol %) of each diamine to the total amount of diamines used. In all of the polyamic acid solutions P1 to P6, the molar fraction of each residue in the polyamic acid in the prepared polyamic acid solution was equal to the molar fraction of each monomer (each of diamines and acid dianhydrides) used in synthesis of the polyamic acid.

TABLE 1

| Polyamic acid | Acid dianhydride [mol %] | | | Diamine [mol %] | | |
|---|---|---|---|---|---|---|
| solution | BPDA | SFDA | ODPA | 4-BAAB | DDS | PDA |
| P1 | — | 100 | — | 100 | — | — |
| P2 | 30 | 70 | — | 100 | — | — |
| P3 | 40 | 60 | — | 100 | — | — |
| P4 | 50 | 50 | — | 90 | 10 | — |
| P5 | — | 95 | 5 | 100 | — | — |
| P6 | — | 100 | — | — | — | 100 |

### <Preparation of Polyimide Film (Laminate)>

Hereinafter, the methods for preparing a polyimide film (laminate) in Examples and Comparative Examples will be described. All of the polyimide precursor compositions used in Examples were prepared in a nitrogen atmosphere.

### Example 1

Into a 300 mL glass separable flask equipped with a stirrer including a stainless steel stirring rod and with a nitrogen inlet tube, 75.0 g of the polyamic acid solution P1 was put. Then, 75.0 g of NMP and 2.56 g of DMI were put into the flask while the flask contents were stirred, and stirring was continued until the flask contents became uniform. Then, while the flask contents were stirred, 2.72 g of AC₂O was put into the flask, and then the flask contents were stirred for 6 hours under an atmosphere at a temperature of 23° C. to obtain a polyimide precursor composition. The obtained polyimide precursor composition was applied using a spin coater onto a glass substrate (manufactured by Corning Incorporated, material: alkali-free glass, thickness: 0.7 mm, size: 100 mm×100 mm), and the resulting product was heated at 80° C. for 30 minutes in the air, and then heated at 430° C. for 30 minutes in a nitrogen atmosphere to obtain a laminate including a polyimide film having a thickness of 10 μm on the glass substrate (laminate of Example 1).

### Examples 2 to 5

Laminates of Examples 2 to 5 were each obtained with the same method as in Example 1, except that the kind of the polyamic acid solution used, the amount of DMI used (added), and the amount of AC₂O used (added) were changed as shown in Table 2.

### Example 6

Into a 300 mL glass separable flask equipped with a stirrer including a stainless steel stirring rod and with a nitrogen inlet tube, 60.0 g of NMP was put as an organic solvent for polymerization. Then, 8.702 g of the compound 1 was put into the flask and dissolved while the flask contents were stirred. Then, 6.298 g of SFDA was added to the flask contents, and then the flask contents were stirred for 24 hours under an atmosphere at a temperature of 23° C. Then, 0.15 g of DMI was added to the flask contents to obtain a polyimide precursor composition P7. The obtained polyimide precursor composition P7 was applied using a spin coater onto a glass substrate (manufactured by Corning Incorporated, material: alkali-free glass, thickness: 0.7 mm, size: 100 mm×100 mm), and the resulting product was heated at 80° C. for 30 minutes in the air, and then heated at 430° C. for 30 minutes in a nitrogen atmosphere to obtain a laminate including a polyimide film having a thickness of 10 μm on the glass substrate (laminate of Example 6).

### Comparative Example 1

The polyamic acid solution P1 was applied using a spin coater onto a glass substrate (manufactured by Corning Incorporated, material: alkali-free glass, thickness: 0.7 mm, size: 100 mm×100 mm), and the resulting product was heated at 120° C. for 30 minutes in the air, and then heated at 430° C. for 30 minutes in a nitrogen atmosphere to obtain a laminate including a polyimide film having a thickness of 10 μm on the glass substrate (laminate of Comparative Example 1).

### Comparative Examples 2 to 6

Laminates of Comparative Examples 2 to 5 were each obtained with the same method as in Comparative Example 1, except that the kind of the polyamic acid solution used was changed as shown in Table 2. A laminate of Comparative Example 6 was obtained with the same method as in Comparative Example 1, except that the polyamic acid solution P6 was used instead of the polyamic acid solution P1, and that a solution obtained by adding a predetermined amount of DMI to the polyamic acid solution P6 was applied onto the glass substrate.

Table 2 shows the kind of the polyamic acid solution used, the amount of DMI used, the amount of AC₂O used, the imidization ratio, the internal stress, the internal stress reduction ratio, the CTE, the YI, the 400 nm transmittance, and the haze in each of Examples 1 to 6 and Comparative Examples 1 to 6. In Table 2, all of the numerical values in the columns of “DMI” and “AC₂O” are the molar equivalent ratio (unit:times molar equivalent) to the amide group of the polyamic acid. In Table 2, “-” in the columns of “DMI” and “AC₂O” means that the relevant component was not used. In Table 2, “P7” in the column of “Polyamic acid solution” means the polyimide precursor composition P7. In Table 2, “-” in the column of the internal stress reduction ratio means that the internal stress reduction ratio was not measured.

TABLE 2

| | Polyamic | DMI | AC₂O | Imidization | Internal | Internal stress | | | 400 nm | |
|---|---|---|---|---|---|---|---|---|---|---|
| | acid | [times molar | [times molar | ratio | stress | reduction ratio | CTE | | transmittance | Haze |
| | solution | equivalent] | equivalent] | [mol %] | [MPa] | [%] | [ppm/K] | YI | [%] | [%] |
| Example 1 | P1 | 0.3 | 0.3 | 40 | 20 | 61 | 17 | 4.8 | 60 | 0.3 |
| Example 2 | P2 | 0.3 | 0.3 | 35 | 20 | 57 | 27 | 5.8 | 46 | 0.4 |
| Example 3 | P3 | 0.3 | 0.3 | 31 | 21 | 22 | 19 | 6.8 | 42 | 0.5 |
| Example 4 | P4 | 0.5 | 0.5 | 44 | 22 | 29 | 24 | 6.3 | 40 | 0.7 |
| Example 5 | P5 | 0.5 | 0.5 | 43 | 32 | 43 | 30 | 6.7 | 57 | 0.6 |
| Example 6 | P7 | 0.06 | — | 48 | 20 | — | 16 | 13.0 | 35 | 0.4 |
| Comparative | P1 | — | — | 0 | 51 | — | 47 | 10.0 | 52 | 0.7 |
| Example 1 | | | | | | | | | | |
| Comparative | P2 | — | — | 0 | 46 | — | 43 | 12.3 | 36 | 0.6 |
| Example 2 | | | | | | | | | | |
| Comparative | P3 | — | — | 0 | 27 | — | 31 | 9.1 | 32 | 0.6 |
| Example 3 | | | | | | | | | | |
| Comparative | P4 | — | — | 0 | 31 | — | 31 | 10.0 | 30 | 0.5 |
| Example 4 | | | | | | | | | | |
| Comparative | P5 | — | — | 0 | 56 | — | 55 | 8.1 | 54 | 0.5 |
| Example 5 | | | | | | | | | | |
| Comparative | P6 | 0.06 | — | 0 | 38 | — | 31 | 16.0 | 30 | 0.5 |
| Example 6 | | | | | | | | | | |

As shown in Table 2, the imidization ratio of the polyimide precursor in each of the polyimide precursor compositions used in Examples 1 to 6 was 10 mol % or more and less than 80 mol % with respect to the total amount of structural units in the polyimide precursor. In Examples 1 to 6, the haze was 1.0% or less. Thus, the polyimide films obtained in Examples 1 to 6 were excellent in transparency. In Examples 1 to 6, the CTE was 30 ppm/K or less. Thus, in the polyimide films obtained in Examples 1 to 6, reduction of the CTE was achieved.

As shown in Table 2, the imidization ratio of the polyamic acid in each of the polyamic acid solutions used in Comparative Examples 1 to 6 was 0 mol % with respect to the total amount of structural units in the polyamic acid. In Comparative Examples 1 to 6, the CTE was more than 30 ppm/K. Thus, in the polyimide films obtained in Comparative Examples 1 to 6, reduction of the CTE was not achieved.

From the above results, it has been shown that the polyimide obtained from the polyimide precursor composition according to one or more embodiments of the present invention can reduce the CTE while enhancing the transparency.

Although the disclosure has been described with respect to only a limited number of embodiments, those skilled in the art, having benefit of this disclosure, will appreciate that various other embodiments may be devised without departing from the scope of the present disclosure. Accordingly, the scope of the invention should be limited only by the attached claims.

1. A polyimide precursor composition comprising a polyimide precursor and an organic solvent, wherein:
the polyimide precursor has a structural unit represented by General Formula (1) and a structural unit represented by General Formula (2); and
the polyimide precursor composition has a content of the structural unit represented by General Formula (2) of 10 mol % or more and less than 80 mol % with respect to a total amount of structural units in the polyimide precursor, 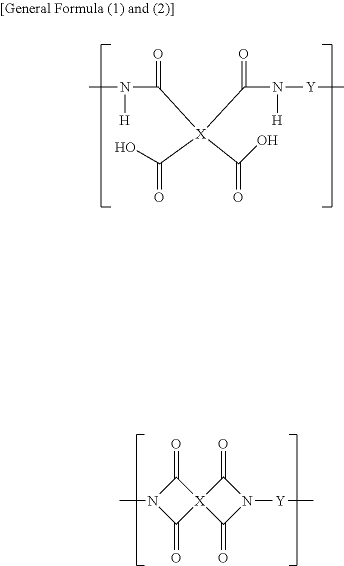
where X includes one or more selected from the group consisting of a tetravalent organic group represented by Chemical Formula (3) and a tetravalent organic group represented by Chemical Formula (4), and Y includes one or more selected from the group consisting of a divalent organic group represented by Chemical Formula (5), a divalent organic group represented by Chemical Formula (6), divalent organic groups represented by General Formula (7), and divalent organic groups represented by General Formula (8), and 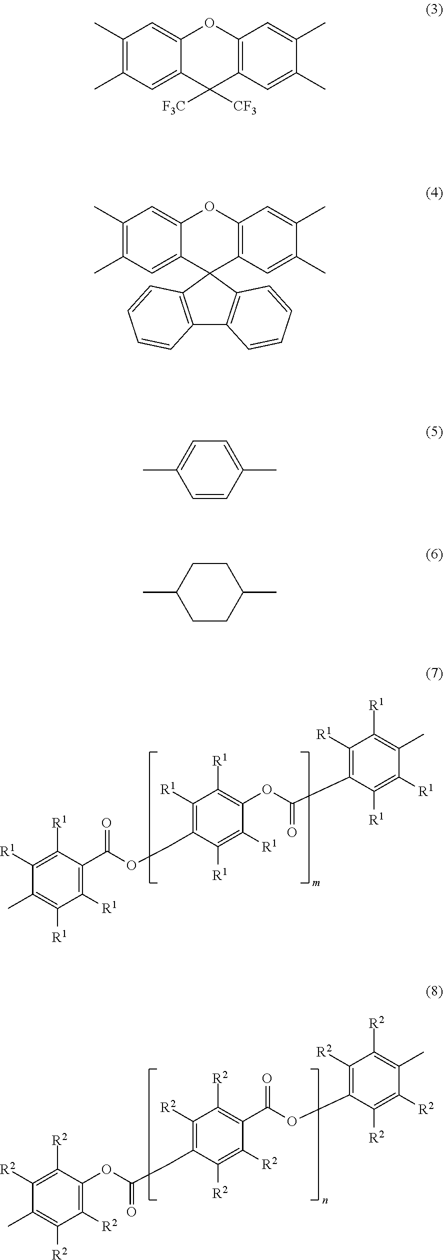
where R¹ and R² each independently represent a monovalent organic group having 1 or more and 12 or less carbon atoms or represent a hydrogen atom, a plurality of R¹s are optionally equal to or different from each other, a plurality of R²s are optionally equal to or different from each other, and m and n each independently represent an integer of 0 or more and 3 or less.

2. The polyimide precursor composition according to claim 1, having a content of one or more residues of 50 mol % or more and 100 mol % or less with respect to a total amount of diamine residues in the polyimide precursor, the one or more residues selected from the group consisting of the divalent organic group represented by Chemical Formula (5), the divalent organic group represented by Chemical Formula (6), the divalent organic groups represented by General Formula (7), and the divalent organic groups represented by General Formula (8).

3. The polyimide precursor composition according to claim 1, wherein, in General Formulas (1) and (2), X further includes one or more selected from the group consisting of a tetravalent organic group represented by Chemical Formula (9), a tetravalent organic group represented by Chemical Formula (10), a tetravalent organic group represented by Chemical Formula (11), a tetravalent organic group represented by Chemical Formula (12), and a tetravalent organic group represented by Chemical Formula (13),

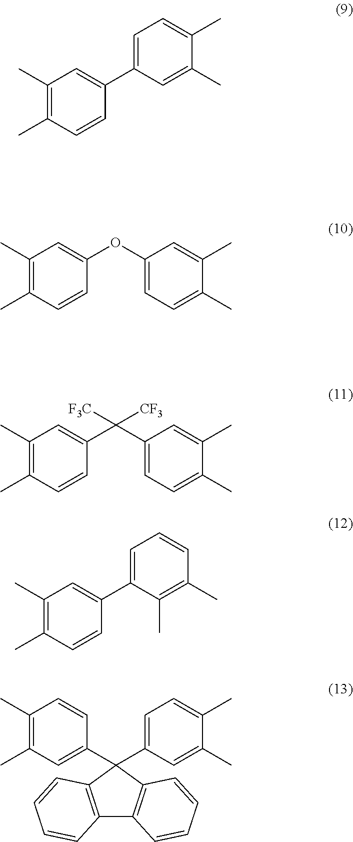

4. The polyimide precursor composition according to claim 3, having a content of one or more residues of 5 mol % or more and 95 mol % or less with respect to a total amount of tetracarboxylic dianhydride residues in the polyimide precursor, the one or more residues selected from the group consisting of the tetravalent organic group represented by Chemical Formula (9), the tetravalent organic group represented by Chemical Formula (10), the tetravalent organic group represented by Chemical Formula (11), the tetravalent organic group represented by Chemical Formula (12), and the tetravalent organic group represented by Chemical Formula (13).

5. The polyimide precursor composition according to claim 1, wherein the organic solvent is one or more selected from the group consisting of N-methyl-2-pyrrolidone, 1-butyl-2-pyrrolidone, 3-methoxy-N,N-dimethylpropanamide, 3-butoxy-N,N-dimethylpropanamide, N,N-dimethylpropionamide, N,N-diethylformamide, and 1,3-dimethyl-2-imidazolidinone.

6. A polyimide film comprising a polyimide having a structural unit represented by General Formula (2), wherein the polyimide film has a linear thermal expansion coefficient of 30 ppm/K or less, 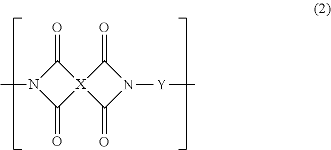
where X includes one or more selected from the group consisting of a tetravalent organic group represented by Chemical Formula (3) and a tetravalent organic group represented by Chemical Formula (4), and Y includes one or more selected from the group consisting of a divalent organic group represented by Chemical Formula (5), a divalent organic group represented by Chemical Formula (6), divalent organic groups represented by General Formula (7), and divalent organic groups represented by General Formula (8), and 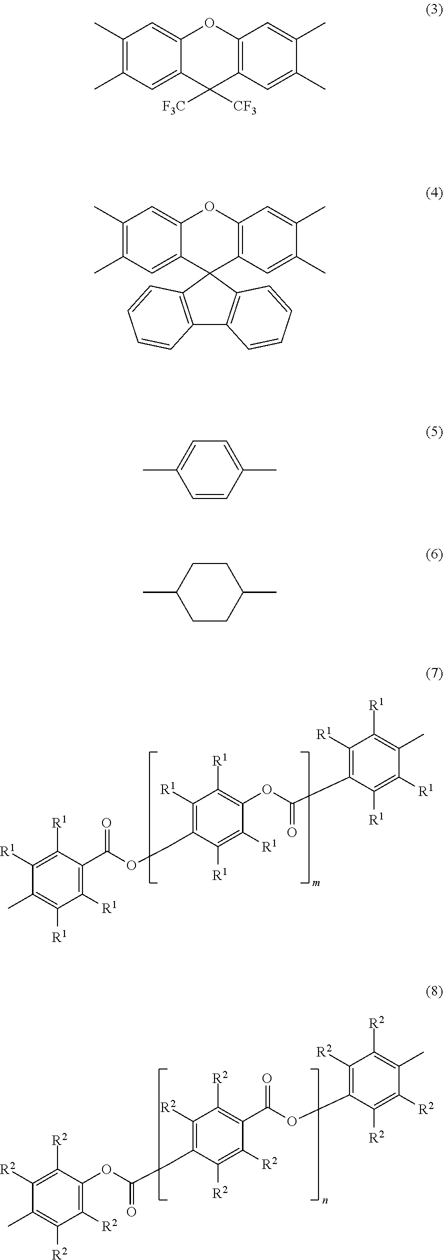
where R¹ and R² each independently represent a monovalent organic group having 1 or more and 12 or less carbon atoms or represent a hydrogen atom, a plurality of R¹s are optionally equal to or different from each other, a plurality of R²s are optionally equal to or different from each other, and m and n each independently represent an integer of 0 or more and 3 or less.

7. The polyimide film according to claim 6, wherein:
a content of one or more residues selected from the group consisting of the divalent organic group represented by Chemical Formula (5), the divalent organic group represented by Chemical Formula (6), the divalent organic groups represented by General Formula (7), and the divalent organic groups represented by General Formula (8) is 50 mol % or more and 100 mol % or less with respect to a total amount of diamine residues in the polyimide;
in General Formula (2), X further includes one or more selected from the group consisting of a tetravalent organic group represented by Chemical Formula (9), a tetravalent organic group represented by Chemical Formula (10), a tetravalent organic group represented by Chemical Formula (11), a tetravalent organic group represented by Chemical Formula (12), and a tetravalent organic group represented by Chemical Formula (13); and
a content of one or more residues selected from the group consisting of the tetravalent organic group represented by Chemical Formula (9), the tetravalent organic group represented by Chemical Formula (10), the tetravalent organic group represented by Chemical Formula (11), the tetravalent organic group represented by Chemical Formula (12), and the tetravalent organic group represented by Chemical Formula (13) is 5 mol % or more and 95 mol % or less with respect to a total amount of tetracarboxylic dianhydride residues in the polyimide,

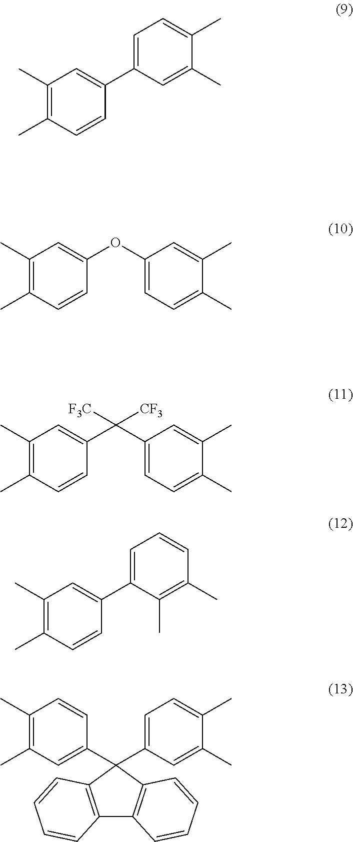

8. The polyimide film according to claim 6, having a haze of 1.0% or less.

9. A laminate comprising a support and the polyimide film according to claim 6.

10. An electronic device comprising the polyimide film according to claim 6 and an electronic element disposed on the polyimide film.

11. An electronic device comprising the laminate according to claim 9 and an electronic element disposed on the polyimide film of the laminate.

12. A method of producing a laminate including a support and a polyimide film, comprising:
applying the polyimide precursor composition of claim 1 onto a support to form a coating film containing the polyimide precursor; and
heating the coating film, thereby imidizing the polyimide precursor to form a polyimide film on the support.

13. A method of producing a polyimide film, comprising:
forming the laminate according to claim 12; and
peeling the polyimide film from the support.

14. A method of producing an electronic device, comprising:
forming the laminate according to claim 12; and
forming an electronic element on the polyimide film.
